(19) United States
(12) Patent Application Publication
(10) Pub. No.: US 2010/0239756 A1
(43) Pub. Date: Sep. 23, 2010

(54) PLASMA PROCESSING APPARATUS AND GAS EXHAUST METHOD

(75) Inventor: Jun Yamashita, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, TOKYO (JP)

(21) Appl. No.: 12/680,659

(22) PCT Filed: Sep. 25, 2008
(86) PCT No.: PCT/JP2008/067296

§ 371 Date: Jun. 7, 2010

(30) Foreign Application Priority Data
Sep. 28, 2007 (JP) 2007-255088

(51) Int. Cl. C23C 16/455

(52) U.S. Cl. 427/248.1; 118/728

(57) ABSTRACT

A plasma processing apparatus is provided for performing plasma processing to a substrate to be processed. The plasma processing apparatus is provided with a processing chamber 2 which forms an inner space 15; a substrate mounting table 3 arranged in the inner space 15 for mounting the substrate W; a processing space forming member 16, which is arranged in the inner space 15, has the inner diameter a1 smaller than the inner diameter a15 of the inner space 15, and partitions a processing space 1 above the substrate mounting table 3 for performing plasma processing; and an exhaust port 6 arranged between an upper end portion 16a of the processing space forming member 16 and an inner wall 15a of the inner space 15 for exhausting gas from the processing space 1.

### FIELD OF THE INVENTION

The present invention relates to a processing apparatus for processing a target substrate such as a semiconductor wafer or the like and a gas exhaust method; and, more particularly, to a plasma processing apparatus for performing plasma processing on a target substrate by using a microwave plasma, and a gas exhaust method.

### BACKGROUND OF THE INVENTION

Recently, with the trend of requirement for high integration and high speed of LSI, a design rule of semiconductor devices forming the LSI becomes finer. Further, scaling up of semiconductor wafers is being accelerated in view of improving production efficiency. Hence, a processing apparatus for processing a target substrate such as a semiconductor wafer or the like needs to deal with miniaturization of devices and scaling up of wafers.

In a recent semiconductor manufacturing process, it is necessary to use a plasma processing apparatus for film formation or etching. Especially, a microwave plasma processing apparatus capable of generating a high-density low electron temperature plasma attracts attention (see, e.g., Japanese Patent Application Publication No. 2004-14262)

As described in the aforementioned Patent Document, in the microwave plasma processing apparatus, a processing gas is generally introduced from an upper portion of a processing space and exhausted from a low portion of the processing space.

Fine semiconductor devices require a high-quality thin film. However, in the microwave plasma processing apparatus, a pressure in the processing space is controlled while introducing the processing gas from the upper portion of the processing space and exhausting it from the lower portion of the processing space, so that the gas is likely to stagnate in the processing space. If the gas stagnates, the gas is excessively dissociated by a plasma and, thus, reaction active species and by-products are excessively generated. This deteriorates a film quality or causes generation of particles, which may affect the manufacture of semiconductor devices.

### SUMMARY OF THE INVENTION

The present invention provides a plasma processing apparatus capable of preventing gas from stagnating in a processing space and supplying clean processing gas to a target substrate, and a gas exhaust method.

In accordance with a first aspect of the invention, there is provided a plasma processing apparatus including: a processing chamber forming an inner space; a substrate mounting table, provided in the inner space, for mounting thereon a target substrate; a processing space forming member, provided in the inner space and having an inner diameter smaller than an inner diameter of the inner space, for partitioning a processing space for performing plasma processing above the substrate mounting table; and a gas exhaust port, disposed between an upper end portion of the processing space forming member and an inner wall of the inner space, for exhausting gas from the processing space.

In accordance with a second aspect of the invention, there is provided a plasma processing apparatus including: a processing chamber forming an inner space; a substrate mounting table, provided in the inner space, for mounting thereon a target substrate; a microwave transmitting plate disposed at an upper portion of the processing chamber so as to face a target substrate mounting surface of the substrate mounting table; a microwave antenna disposed on the microwave transmitting plate; a processing space forming member, provided in the inner space and having an inner diameter smaller than an inner diameter of the inner space, for partitioning a processing space for performing plasma processing above the substrate mounting table; a processing gas inlet port, formed at the processing space forming member, for introducing a processing gas into the processing space from a vicinity of the substrate mounting table; and a gas exhaust port, provided between an upper end portion of the processing space forming member and an inner wall of the inner space, for exhausting gas from the processing space.

In accordance with a third aspect of the invention, there is provided a gas exhaust method of a plasma processing apparatus including a processing chamber forming an inner space; a substrate mounting table provided in the inner space, for mounting thereon a target substrate; a processing space forming member disposed in the inner space, having an inner diameter smaller than an inner diameter of the inner space, for partitioning a processing space for performing plasma processing above the substrate mounting table; and a gas exhaust port provided between an upper end portion of the processing space forming member and an inner wall of the inner space, for exhausting gas from the processing space, the gas exhaust method including: exhausting gas in the processing space from a portion above the substrate mounting table.

In accordance with a fourth aspect of the invention, there is provided A gas exhaust method for a plasma processing apparatus including a processing chamber forming an inner space; a substrate mounting table provided in the inner space, for mounting thereon a target substrate; a microwave transmitting plate disposed at an upper portion of the processing chamber so as to face a target substrate mounting surface of the substrate mounting table; and a microwave antenna disposed on the microwave transmitting plate, the gas exhaust method including: providing in the inner space a processing space forming member having an inner diameter smaller than an inner diameter of the inner space, for partitioning a processing space for performing plasma processing above the substrate mounting table; introducing a processing gas from a vicinity of the substrate mounting table into the processing space; and exhausting the gas in the processing space from a portion above the substrate mounting table.

### BRIEF DESCRIPTION OF THE DRAWINGS

FIG. 1 is a cross sectional view schematically showing an example of a plasma processing apparatus in accordance with a first embodiment of the present invention.

FIG. 2A describes a gas flow in a processing space.

FIG. 2B illustrates a gas flow in a processing space.

FIG. 3 provides a cross sectional view schematically depicting an example of a plasma processing apparatus in accordance with a second embodiment of the present invention.

FIG. 4 offers a specific and more detailed cross sectional view of the apparatus of FIG. 3.

FIG. 5 presents a top view describing an example of a processing space forming member 16.

FIG. 6 represents a cross sectional view taken along line IV-IV of FIG. 5.

FIG. 7A depicts a gas flow in a processing space.

FIG. 7B shows a gas flow in a processing space.

### DETAILED DESCRIPTION OF THE EMBODIMENT

Hereinafter, the embodiments of the present invention will be described with reference to the accompanying drawings.

### First Embodiment

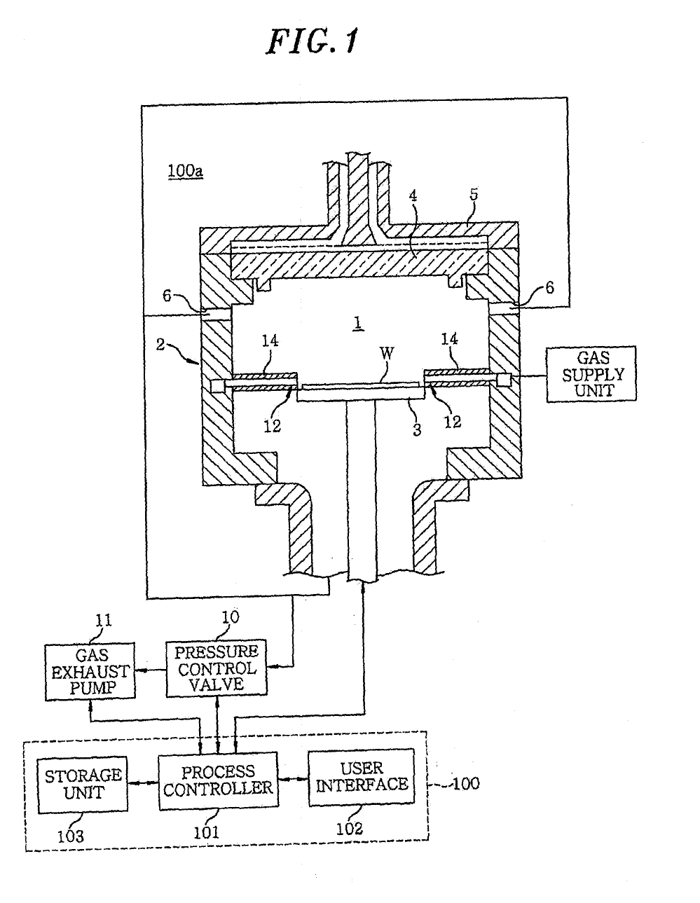

FIG. 1 is a cross sectional view schematically showing an example of a plasma processing apparatus in accordance with a first embodiment of the present invention.

As shown in FIG. 1, a plasma processing apparatus 100a in accordance with the first embodiment includes: a processing chamber 2 forming a processing space 1 for performing plasma processing; a substrate mounting table 3 provided in the processing space 1, for mounting thereon a target substrate W; a microwave transmitting plate 4 installed at an upper part of the processing chamber 2 which faces a target substrate mounting surface of the substrate mounting table 3; a microwave antenna 5 disposed above the microwave transmitting plate 4; and gas exhaust ports 6 provided above the substrate mounting table 3, for exhausting gas from the processing space 1.

The apparatus 100a controls a pressure in the processing space 1 within a range of, e.g., 0.05 Torr to a few Torr during plasma processing in the processing space 1. For that reason, the gas exhaust ports 6 are connected to a gas exhaust unit, e.g., a gas exhaust pump 11, via a pressure control unit, e.g., a pressure control valve 10.

The apparatus 100a includes a control unit 100 for controlling various components of the apparatus 100a, i.e., the pressure control valve 10, the gas exhaust pump 11 and the like. The control unit 100 has a process controller 101, a user interface 102 and a storage unit 103. The controller 101 controls the various components. The interface 102 has a display and a keyboard. An operator inputs a command or the like for managing the apparatus 100a by using the keyboard while monitoring the display which visually displays, e.g., an operational status of the apparatus 100a.

The storage unit 103 stores therein recipes such as control programs for implementing processes executed by the apparatus 100a under the control of the controller 101 or programs for operating various components of the processing apparatus based on various data and processing conditions. The recipes are stored in a storage medium of the storage unit 103. The storage medium may be a hard disc or a portable one such as a CD-ROM, a DVD, a flash memory or the like. Further, the recipes may be transmitted from another apparatus via, e.g., a dedicated line. As needed, a necessary recipe is retrieved from the storage unit 103 by, e.g., an instruction from the interface 102 and executed by the controller 101, thereby performing a desired process in the apparatus 100a.

In the apparatus 100a in accordance with the first embodiment, the gas in the processing space 1 is exhausted from a portion above the substrate mounting table 3. Since the gas in the processing space 1 is exhausted from the portion above the substrate mounting table 3, the plasma processing apparatus can prevent the gas from stagnating in the processing space 1.

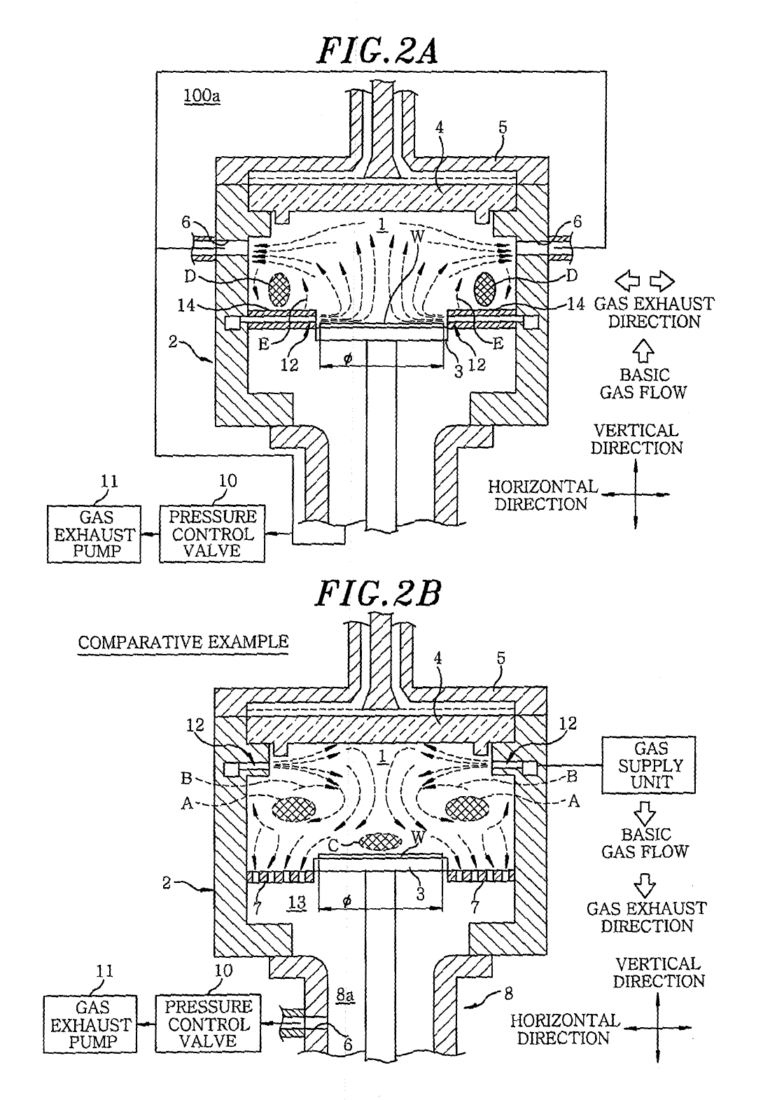

FIGS. 2A and 2B compare gas flows in the processing spaces 1 of the apparatus 100a and a comparative apparatus. FIG. 2A shows the apparatus 100a, and FIG. 2B depicts the comparative apparatus.

In the comparative apparatus shown in FIG. 2B, a processing gas is introduced from an upper portion of the processing space 1 and exhausted from a lower portion of the processing space 1. Especially, the processing gas is exhausted from a gas exhaust space 8a communicating with a lower space 13 which is formed below the substrate mounting table 3 after passing through a baffle plate 7 disposed around the substrate mounting table 3 in parallel with the substrate mounting table 3.

As described above, the plasma processing apparatus controls a pressure in the processing space 1 within a range from, e.g., 0.05 Torr to a few Torr during plasma processing in the processing space 1. For that reason, the gas exhaust ports 6 is connected to the gas exhaust pump 11 via the pressure control valve 10, as can be seen from FIGS. 2A and 2B.

In the comparative example illustrated in FIG. 2B, the gas in the processing space 1 is exhausted in a direction normal to the substrate mounting table 3 via the baffle plate 7 disposed in parallel with the substrate mounting table 3, the baffle plate 7 having a plurality of openings. In the comparative example, gas inlet ports 12 are provided at an upper portion of the processing space 1, so that the gas in the processing space 1 basically flows downward from top to bottom.

The lower space 13 formed below the baffle plate 7 communicates with the gas exhaust space 8a of a gas exhaust chamber 8. The gas exhaust space 8a is exhausted by the gas exhaust pump 11 via the pressure control valve 10, so that a pressure in the lower space 13 communicating with the gas exhaust space 8a is low. However, a pressure in the processing space 1 provided above the lower space 13 becomes higher than that in the lower space 13 by the amount depending on the exhaust conductance of the baffle plate 7. Accordingly, the processing gas that has been introduced into the processing space 1 but has not passed through the baffle plate 7 becomes residual gas, and this residual gas stagnates above the baffle plate 7 (see reference character “AA”).

The residual gas is mostly the processing gas that has passed through a space above the target substrate W and has been used for plasma processing such as film formation or the like. Some of the stagnant residual gas returns to the space above the target substrate W along the flow of the processing gas injected from the gas inlet ports 12 (see reference character “B”). The processing gas just injected from the gas inlet ports 12 is the unused clean processing gas that has not passed through the space above the target substrate W.

If the fresh processing gas is mixed with the used processing gas, the cleanness of the processing gas supplied to the space above the target substrate W decreases. In addition, the mixed gas stagnates above the baffle plate 7 and returns to the space above the target substrate W along the flow of the processing gas injected from the gas inlet ports 12. Hence, a circulation flow of the residual gas which decreases the cleanness of the processing gas is generated in the processing space 1. The stagnant residual gas and the residual gas moving along the circulation flow stagnate long in the processing space 1 while being exposed to a plasma for a long time and thus may be excessively dissociated. This deteriorates a film quality of a thin film or causes generation of particles.

Besides, in the comparative example, the baffle plate 7 is installed below the target substrate W. Therefore, the gas positioned above the target substrate needs to pass through the baffle plate 7 after moving in a horizontal direction with respect to the surface of the target substrate W. Since, however, a central portion of the target substrate W is distant from the baffle plate 7, it is difficult for the processing gas positioned above the central portion of the target substrate W to pass through the baffle plate 7.

Accordingly, above the central portion of the target substrate W, the flow of the processing gas is apt to be slowed down, and a stagnant zone C where the processing gas stagnates can be formed easily. The stagnant zone C is more likely to be formed as a dimension of the target substrate W, e.g., a diameter Φ of a semiconductor wafer in the case where the target substrate W is a semiconductor wafer, increases. For example, the stagnant zone C is more likely to be formed in the case of a wafer having a diameter Φ greater than or equal to 300 mm than in the case of a wafer having a diameter Φ smaller than 300 mm.

On the other hand, in the apparatus 100a, the gas in the processing space 1 is exhausted from a portion above the substrate mounting table 3, as depicted in FIG. 2A. In this example, the gas is exhausted in a direction parallel to the substrate mounting table 3 via gas exhaust ports 6 formed at a sidewall of the processing chamber 2 above the substrate mounting table 3. Moreover, in the apparatus 100a, the gas inlet ports 12 are provided at a lower side of the processing space 1, e.g., near the substrate mounting table in this example. Therefore, the gas in the processing space 1 basically flows upward from bottom to top.

Unlike the comparative example, the apparatus 100a does not have the baffle plate 7. Due to the absence of the baffle plate 7, even if the gas exhaust ports 6 is connected to the gas exhaust pump 11 via the pressure control valve 10, the residual gas does not stagnate above the baffle plate 7 unlike in the comparative example.

Instead, around the substrate mounting table 3, the apparatus 100a has a ring plate 14 provided parallel to the substrate mounting table 3. This is because the gas inlet ports 12 need to be positioned near the substrate mounting table 3. The gas inlet ports 12 are formed at the ring plate 14. The residual gas that has not passed through the gas exhaust ports 6 move downward toward the ring plate 14 and may stagnate above the ring plate 14 (see reference character “D”). Some of the stagnant residual gas may flow along the flow of the processing gas injected from the gas inlet ports 12.

However, this flow moves upward on the ring plate 14 while heading toward the gas exhaust ports 6 without heading toward the space above the target substrate W (see reference character “E”). The flow moving upward toward the gas exhaust ports 6 is different from the flow in the comparative example which moves downward above the target substrate W. In the apparatus 100a, even if the stagnant residual gas is generated, it moves upward toward the gas exhaust ports 6 and thus is less likely to be mixed with unused fresh processing gas compared to the case of the comparative apparatus.

Hence, in the apparatus 100a, it is difficult for the residual gas to return to the space above the target substrate W, and this can improve a film quality of a thin film to be formed compared to the case of the comparative apparatus. Besides, the amount of particles decreases, so that reduction in the production yield can be prevented.

Further, in the apparatus 100a, the gas exhaust ports 6 are provided above the substrate mounting table 3 and also above the processing gas inlet ports 12. The processing gas inlet ports 12 are positioned near an edge of the target substrate W. The processing gas is injected in a horizontal direction from the edge of the target substrate W toward a central portion of the target substrate W. Therefore, the stagnant zone C where the processing gas stagnates at the central portion of the target substrate W is less likely to be formed compared to the case of the comparative example in which the processing gas is drawn from the edge of the target substrate W in a horizontal direction and exhausted after changing the exhaust direction to a vertical direction. This advantage can be obtained even if a diameter Φ of the target substrate, e.g., a wafer, increases.

Therefore, in the apparatus 100a, even if a diameter Φ of the wafer is greater than or equal to, e.g., 300 mm, it is possible to obtain the advantage in which the stagnant zone C is less likely to be formed above the central portion of the target substrate W.

Moreover, since the processing gas is constantly horizontally injected from the edge of the target substrate W toward the central portion of the target substrate W, the advantage in which the fresh processing gas can be constantly supplied to the target substrate W during plasma processing can be obtained.

Due to the above-described advantages, the apparatus 100a can improve a film quality of a thin film to be formed and reduce the amount of particles compared to the comparative example. As a consequence, reduction in the production yield can be prevented.

As described above, in accordance with the first embodiment, it is possible to provide a plasma processing apparatus, which is capable of preventing a gas from stagnating in a processing space and constantly supplying a fresh processing gas to a target substrate, and a gas exhaust method therefor.

### Second Embodiment

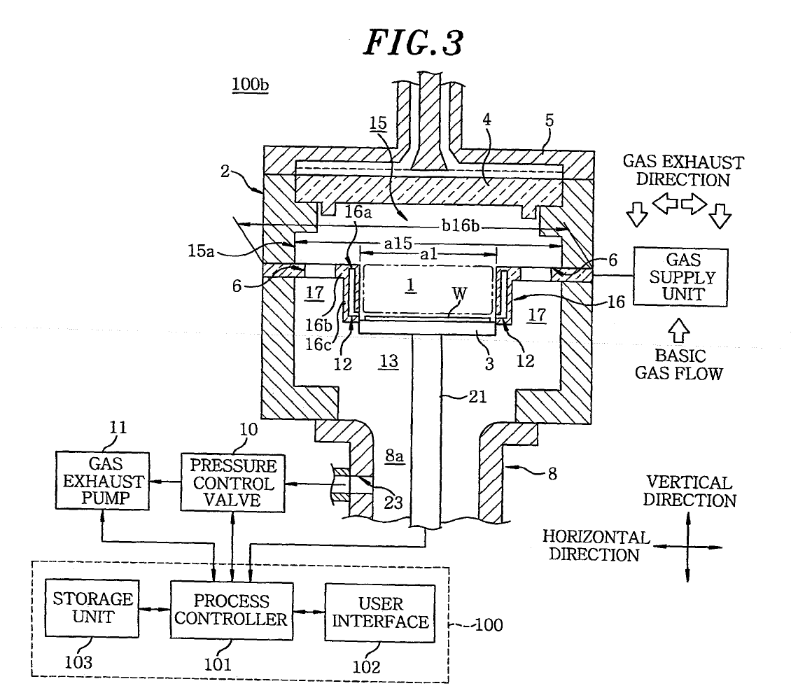

FIG. 3 provides a cross sectional view schematically depicting an example of a plasma processing apparatus in accordance with a second embodiment of the present invention. Like reference characters will be used in FIG. 3 for like parts shown in FIG. 1, and redundant description will be omitted.

As described in FIG. 3, a plasma processing apparatus 100b in accordance with the second embodiment is different from the plasma processing apparatus 100a in accordance with the first embodiment in that it includes: a processing chamber 2 forming an inner space 15; a substrate mounting table 3 provided in the inner space 15, for mounting thereon a target substrate W; a microwave transmitting plate 4 installed at an upper part of the processing chamber 2 which faces a target substrate mounting surface of the substrate mounting table 3; a microwave antenna 5 disposed above the microwave transmitting plate 4; and a processing space forming member 16 provided in the inner space 15.

The processing space forming member 16 has an inner diameter a1 smaller than an inner diameter a15 of the inner space 15 and partitions the processing space 1 for performing plasma processing above the substrate mounting table 3. The processing space forming member 16 is provided with processing gas inlet ports 12 for introducing a processing gas from a vicinity of the substrate mounting table 3 into the processing space 1.

The gas exhaust ports 6 are provided between an upper end portion 16a of the processing space forming member 16 and an inner wall 15a of the inner space 15. In this example, the gas exhaust ports 6 are provided outside the processing space 1 in parallel with the substrate mounting table 3. The gas exhaust direction of the gas exhaust ports 6 is perpendicular to the substrate mounting table 3.

In this example, a flange portion 16b having an outer diameter b16b greater than or equal to the inner diameter a15 of the processing chamber 2 is formed at the upper end portion 16a of the processing space forming member 16. The gas exhaust ports 6 are installed at the flange portion 16b. The gas exhaust ports 6 installed at the flange portion 16b are provided inside the processing chamber 2 while facing the inner space 15.

Formed below the gas exhaust ports 6 are a cylindrical space 17 disposed between an outer wall of an intermediate portion 16c of the processing space forming member 16 and the inner wall of the processing chamber 2. In this example, the cylindrical space 17 serves as a gas exhaust passage.

A lower space 13 is formed below the substrate mounting table 3 of the processing chamber 2 and communicates with a gas exhaust space 8a connected to a gas exhaust pump 11 of a gas exhaust chamber 8. The gas exhaust passage, i.e., the space 17, communicates with the lower space 13, i.e., the gas exhaust space 8a.

Although a loading/unloading port for loading and unloading the target substrate W into and from the processing space 1 is not particularly illustrated in FIG. 3, when an outer diameter of the substrate mounting table 3 is smaller than the inner diameter a1 of the processing space forming member 16, for example, the loading/unloading port can be formed at a sidewall facing the inner space 15 of the processing chamber 2 and positioned above the upper end portion of the processing space forming member 16. In that case, the substrate mounting table 3 is raised and lowered in the processing space 1 inside the processing space forming member 16.

In addition, the loading/unloading port can be formed at a sidewall of the processing chamber 2 which is disposed horizontally with respect to the substrate mounting table 3 while facing toward the processing space 1. In that case, it is possible to obtain the advantage that it is unnecessary to raise and lower the substrate mounting table 3 during loading and unloading of the target substrate W. Moreover, in this configuration, if loading and unloading of the target substrate W is hindered by the processing space forming member 16, a cutout portion corresponding to the loading/unloading port can be formed at the processing space forming member 16 in order to prevent the loading and unloading of the target substrate W from being hindered.

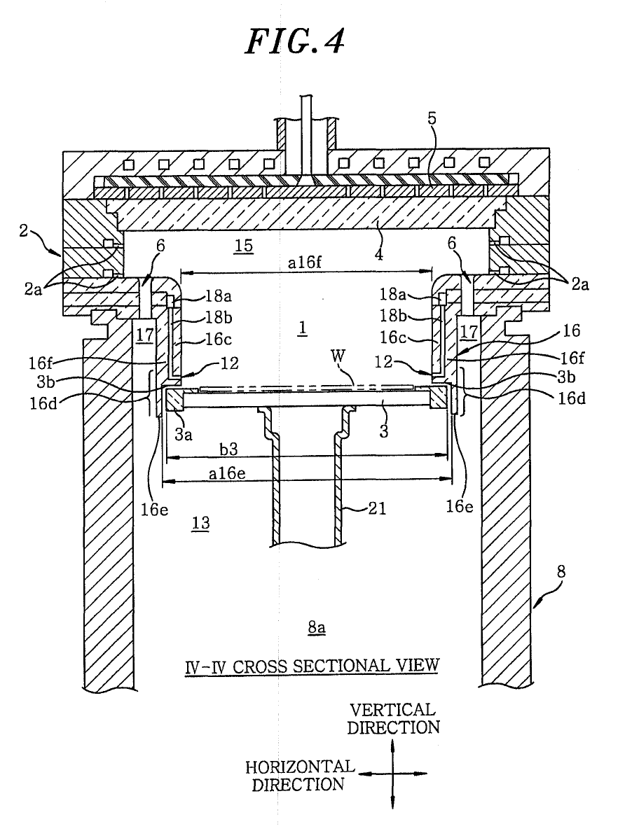

FIG. 4 offers a specific and more detailed cross sectional view of the apparatus 100b shown in FIG. 3.

As can be seen from FIG. 4, a spot facing hole is formed at a lower end portion 16d of the processing space forming member 16, wherein the spot facing hole includes a first portion 16e having an inner diameter a16e greater than an outer diameter b3 of the substrate mounting table 3 and a second portion 16f having an inner diameter a16f smaller than the outer diameter b3 of the substrate mounting table 3. In this example, the substrate mounting table 3 is accommodated in the first portion 16e. Further, in this example, a focus ring 3a is mounted on the substrate mounting table 3, and the outer diameter b3 of the substrate mounting table 3 corresponds to the outer diameter of the focus ring 3a mounted thereon.

In this example, a clearance 3b having an L-shaped cross section which communicates with the processing space 1 and the lower space 13 (unified with the gas exhaust space 8a in this example) is formed between the first portion 16e and the substrate mounting table 3 onto which the focus ring 3a is mounted. In this example, the processing gas may have a chance to be exhausted from the processing space 1 via the clearance 3b. In this example, however, the flow of the processing gas is suppressed by decreasing an exhaust conductance of the clearance 3b compared to that of the gas exhaust ports 6 by way of narrowing the clearance 3b and, further, by making the clearance 3b have an L-shaped. In other words, by reducing the exhaust conductance of the clearance 3b compared to that of the gas exhaust ports 6, the exhaust of the processing gas from the processing space 1 via the clearance 3b is suppressed. In addition, backflow of the used processing gas from the lower space 13 (gas exhaust space 8a) can be prevented.

Further, openings 2a formed at the sidewall facing the inner space 15 of the processing chamber 2 serve as gas inlet ports for introducing dilution gas, e.g., Ar gas, N₂ gas or the like, into the inner space 15.

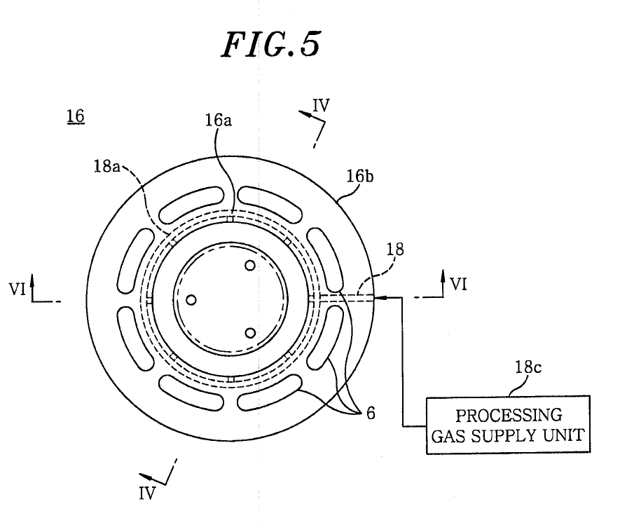

FIG. 5 is a top view showing an example of the processing space forming member 16 of the apparatus 100b. Further, FIG. 4 depicts a cross sectional view taken along the line IV-IV of FIG. 5.

As shown in FIG. 5, a plurality of gas exhaust ports 6 is formed at the flange portion 16b. A main processing gas introducing passage 18 (first processing gas passage) for guiding a processing gas to processing gas inlet ports 12 is horizontally formed between the gas exhaust ports 6 of the flange portion. The main processing gas introducing passage 18 is connected to a processing gas supply unit 18c provided outside the processing chamber 2.

An annular processing gas introducing passage 18a (third processing gas passage) is formed horizontally in the upper end portion 16a of the processing gas forming member 16. The annular processing gas introducing passage 18a is connected to the main processing gas introducing passage 18.

Besides, an auxiliary processing gas introducing passage 18b (second processing gas passage) is formed vertically in the intermediate portion 16c of the processing space forming member 16 (see FIG. 4). The auxiliary processing gas introducing passage 18b connects the annular processing gas introducing passage 18a and the processing gas inlet ports 12.

Namely, in this example, the processing gas is guided to the processing gas inlet ports 12, which are formed at the lower end portion 16d of the processing space forming member 16 and positioned close to the edge of the target substrate W, via the processing gas introducing passage 18, the annular processing gas introducing passage 18a and the auxiliary processing gas introducing passage 18b.

Further, in this example, the processing gas inlet ports 12 are installed at the second portion 16f of the processing space forming member 16 which has the inner diameter a1 smaller than the outer diameter b3 of the substrate mounting table 3, as can be seen from FIG. 4. By forming the processing gas inlet ports 12 at the second portion 16f, the processing gas inlet ports 12 can be positioned closer to the edge of the target substrate W.

Furthermore, in this example, the substrate mounting table 3 is accommodated in the first portion 16e, and the processing gas is introduced into the processing space 1 from a portion above the substrate mounting table 3.

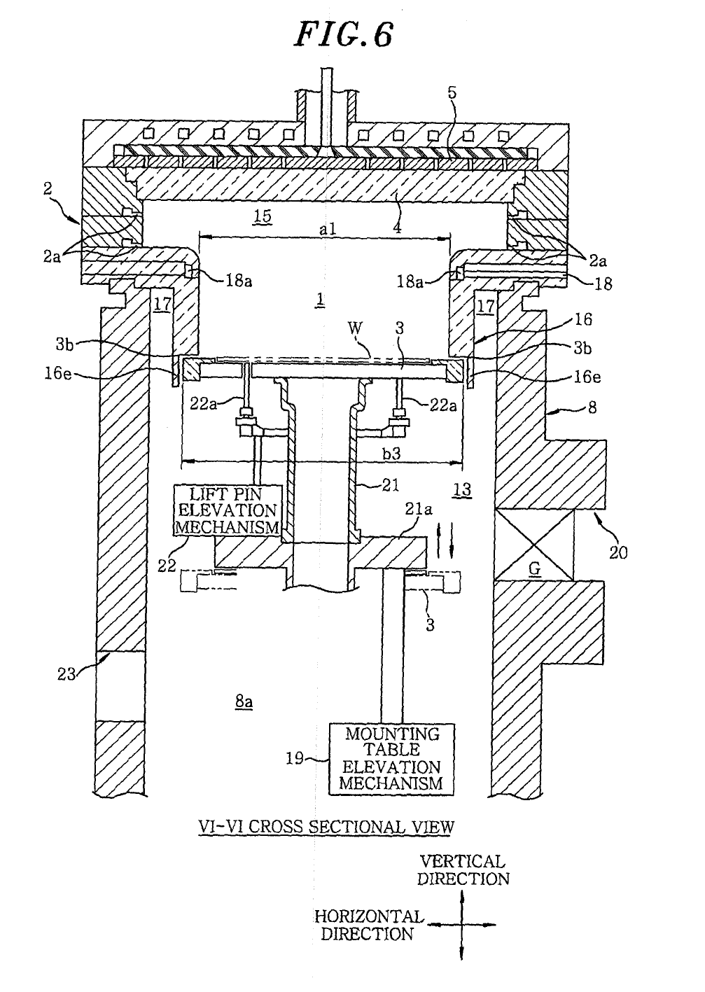

FIG. 6 offers a cross sectional view taken along the line VI-VI of FIG. 5.

As dipicted in FIG. 6, in this example, the inner diameter a1 of the processing space forming member 16 is smaller than the outer diameter b3 of the substrate mounting table 3. Therefore, in this example, the target substrate W is loaded and unloaded by using the lower space 13 formed below the substrate mounting table 3 of the processing chamber 2. A mounting table elevation mechanism 19 for raising and lowering the substrate mounting table 3 is provided in the lower space 13. The mounting table elevation mechanism 19 raises and lowers the substrate mounting table 3 between the lower space 13 and the processing space forming member 16.

A loading/unloading port 20 for loading and unloading the target substrate W into and from the processing chamber 2 is provided at a sidewall of the lower space 13. A gate valve G opens and closes the loading/unloading port 20.

The mounting table elevation mechanism 19 raises and lowers the substrate mounting table 3 between the loading/unloading port 20 and the lower end portion 16d of the processing space forming member 16. In this example, especially, the substrate mounting table 3 is raised until the clearance 3b having the L-shaped cross section is formed between the substrate mounting table 3 and the first portion 16e. Further, the substrate mounting table 3 is positioned close to the processing space forming member 16 so that the exhaust conductance of the clearance 3b becomes smaller than that of the gas exhaust ports 6.

The substrate mounting table 3 is supported by a supporting column 21 disposed in the lower space 13. The supporting column 21 has a hollow inner portion. Although it is not particularly illustrated, control lines and the like for controlling a temperature of a heater provided in the substrate mounting table 3 are provided in the cavity of the supporting column 21.

Besides, in this example, a flange portion 21a is formed in the middle of the supporting column 21, and a lift pin elevation mechanism 22 is attached onto the flange portion 21a. The lift pin elevation mechanism 22 vertically moves lift pins 22a for raising and lowering the target substrate W mounted on the substrate mounting table 3 while penetrating the substrate mounting table 3. Although three lift pins 22a are provided as shown in the top view of FIG. 5, only two are illustrated in FIG. 6.

A main gas exhaust port 23 is formed at a sidewall of the lower space 13 and is connected to a gas exhaust unit, e.g., the gas exhaust pump 11, via a pressure control unit for controlling a pressure in the processing space 1, e.g., the pressure control valve 10 such as an APC (Auto Pressure Control) valve or the like, as can be seen in FIG. 3.

In the second embodiment, the processing gas is also horizontally injected from a vicinity of the edge of the target substrate W, and the gas in the processing space 1 is exhausted through a portion above the target substrate W, as in the first embodiment. Therefore, it is difficult for the gas to stagnate in the processing space, and fresh processing gas can be constantly supplied to the target substrate W.

In the second embodiment, the gas exhaust ports 6 are provided outside the processing space 1, and gas is exhausted in the vertical direction. With this configuration, the second embodiment can provide the following advantages compared to the first embodiment.

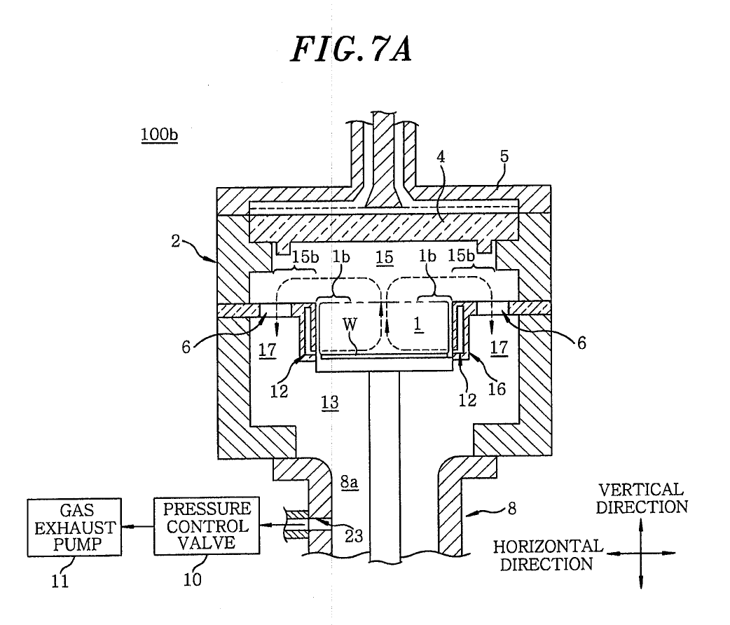

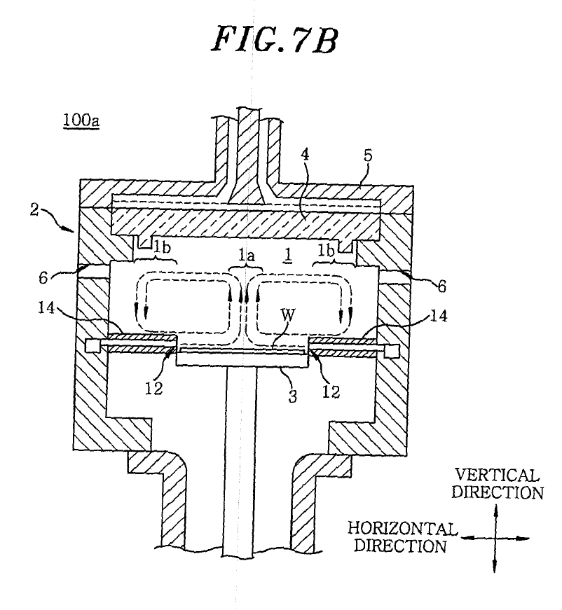

FIGS. 7A and 7B compare gas flows, especially convections of gas, in the processing spaces 1 of the apparatus 100a and the apparatus 100b. FIG. 7A shows the apparatus 100b (second embodiment), and FIG. 7B describes the apparatus 100a (first embodiment).

As illustrated in FIG. 7B, in the apparatus 100a, the processing gas is introduced from a lower portion of the processing space 1 and exhausted through an upper portion of the processing space 1. In the basic convection in the processing space 1 of this configuration, the processing gas moves upward at the central portion 1a of the processing space 1 and then moves toward a circumferential edge 1b of the processing space 1. Further, the processing gas moves downward at the circumferential edge 1b and then moves toward the central portion 1a.

In the apparatus 100b as shown in FIG. 7A, the processing gas is also introduced from the lower portion of the processing space 1 and exhausted through the upper portion of the processing space 1 as in the apparatus 100a. Namely, the basic convection of gas in this case is the same as that in the apparatus 100a.

Since, however, the gas exhaust ports 6 are provided outside the processing space 1 and gas is exhausted in the vertical direction, the processing gas that has reached a circumferential edge 1b of the processing space 1 moves toward a circumferential edge 15b of the inner space 15 having an inner diameter greater than that of the processing space 1. The processing gas that has reached the circumferential edge 15b is exhausted to the space 17 via the gas exhaust ports 6 disposed below the circumferential edge 15b. The space 17 is separated from the processing space 1 by the processing space forming member 16, so that it is difficult for the processing gas exhausted to the space 17 to return to the processing space 1.

Moreover, the processing gas that has not been completely exhausted may stagnate at the circumferential edge 15b of the inner space 15 formed above the gas exhaust ports 6. Since, however, the inner diameter a1 of the processing space 1 is smaller than the inner diameter a15 of the inner space 15 as depicted in FIG. 3, a pressure in the processing space 1 is likely to become higher than that in the inner space 15. Hence, it is also difficult for the processing gas stagnating in the circumferential edge 15b of the inner space 15 to return to the processing space 1.

Namely, in the apparatus 100b in accordance with the second embodiment, the gas exhaust ports 6 are provided outside the processing space 1, and gas is exhausted in the direction perpendicular to the substrate mounting table 3. Accordingly, it is difficult for the processing gas that has passed through the processing space 1 to return to the processing space 1.

Therefore, the apparatus 100b in accordance with the second embodiment is more advantageous in that fresh processing gas can be constantly supplied to the target substrate W mounted in the processing space 1 compared to the apparatus 100a in accordance with the first embodiment.

While the invention has been shown and described with respect to the embodiments, the present invention can be variously changed without being limited to the above-described embodiments.

In the above-described embodiments, a film forming apparatus has been described as an example of a plasma processing apparatus. The present invention may be used for film formation of silicon or a high-k film having a high dielectric constant in addition to film formation of, e.g., a silicon oxide film or a silicon nitride film. Further, it can also be used for modification of various films, etching or the like other than film formation.

Furthermore, in the above-described embodiments, the microwave plasma processing apparatus for performing plasma processing on a target substrate by using a microwave plasma has been described as an example of a plasma processing apparatus. The microwave antenna of the microwave plasma processing apparatus may be, e.g., a radial line slot antenna (RLSA) or a planar microwave antenna other than the RLSA antenna.

In addition, the present invention is not limited to a microwave plasma processing apparatus and may also be applied to any plasma processing apparatus.

What is claimed is:

1. A plasma processing apparatus comprising:
a processing chamber forming an inner space;
a substrate mounting table, provided in the inner space, for mounting thereon a target substrate;
a processing space forming member, provided in the inner space and having an inner diameter smaller than an inner diameter of the inner space, for partitioning a processing space for performing plasma processing above the substrate mounting table; and
a gas exhaust port, disposed between an upper end portion of the processing space forming member and an inner wall of the inner space, for exhausting gas from the processing space.

2. The plasma processing apparatus of claim 1, wherein a processing gas inlet port for introducing a processing gas into the processing space is installed at the processing space forming member.

3. A plasma processing apparatus comprising:
a processing chamber forming an inner space;
a substrate mounting table, provided in the inner space, for mounting thereon a target substrate;
a microwave transmitting plate disposed at an upper portion of the processing chamber so as to face a target substrate mounting surface of the substrate mounting table;
a microwave antenna disposed on the microwave transmitting plate;
a processing space forming member, provided in the inner space and having an inner diameter smaller than an inner diameter of the inner space, for partitioning a processing space for performing plasma processing above the substrate mounting table;
a processing gas inlet port, formed at the processing space forming member, for introducing a processing gas into the processing space from a vicinity of the substrate mounting table; and
a gas exhaust port, provided between an upper end portion of the processing space forming member and an inner wall of the inner space, for exhausting gas from the processing space.

4. The plasma processing apparatus of claim 1, wherein a flange portion having an outer diameter greater than or equal to an inner diameter of the processing chamber is formed at the upper end portion of the processing space forming member, and the gas exhaust port is provided at the flange portion.

5. The plasma processing apparatus of claim 4, wherein the gas exhaust port is provided outside the processing space and is configured to exhaust gas in a direction perpendicular to the substrate mounting table.

6. The plasma processing apparatus of claim 5, wherein a space disposed between an outer wall of an intermediate portion of the processing space forming member and an inner wall of the processing chamber is formed below the gas exhaust port and serves as a gas exhaust passage.

7. The plasma processing apparatus of claim 6, wherein a lower space is formed below the substrate mounting table of the processing chamber and communicates with a gas exhaust space connected to a gas exhaust pump, and the gas exhaust passage communicates with the gas exhaust space.

8. The plasma processing apparatus of claim 7, wherein a spot facing hole including a first portion having an inner diameter greater than an outer diameter of the substrate mounting table and a second portion having an inner diameter smaller than the outer diameter of the substrate mounting table is formed at a lower end portion of the processing space forming member, and the substrate mounting table is accommodated in the first portion.

9. The plasma processing apparatus of claim 8, wherein a clearance having an L-shaped cross section which communicates with the processing space and the gas exhaust space is formed between the substrate mounting table and the first portion, and an exhaust conductance of the clearance having an L-shaped cross section is smaller than an exhaust conductance of the gas exhaust port.

10. The plasma processing apparatus of claim 1, wherein a plurality of gas exhaust ports is provided at the flange portion, and a processing gas introducing passage for guiding the processing gas to the processing gas inlet port includes:
a main processing gas introducing passage formed between the gas exhaust ports of the flange portion and connected to a processing gas supply unit provided outside the processing chamber;
an annular processing gas introducing passage formed at the upper end portion of the processing space forming member and connected to the main processing gas introducing passage; and
an auxiliary processing gas introducing passage formed at an intermediate portion of the processing space forming member, for connecting the annular processing gas introducing passage and the processing gas inlet port.

11. The plasma processing apparatus of claim 10, wherein a spot facing hole including a first portion having an inner diameter greater than an outer diameter of the substrate mounting table and a second portion having an inner diameter smaller than the outer diameter of the substrate mounting table is formed at a lower end portion of the processing space forming member, and the processing gas inlet port is formed at the second portion.

12. The plasma processing apparatus of claim 11, wherein the substrate mounting table is accommodated in the first portion, and the processing gas is introduced into the processing space from a portion above the substrate mounting table.

13. The plasma processing apparatus of claim 1, wherein an inner diameter of the processing space forming member is smaller than an outer diameter of the substrate mounting table.

14. The plasma processing apparatus of claim 13, wherein a lower space is formed below the substrate mounting table of the processing chamber; a mounting table elevation mechanism for raising and lowering the substrate mounting table is provided at the lower space; and the substrate mounting table is raised and lowered by the mounting table elevation mechanism between the lower space and the processing space forming member.

15. The plasma processing apparatus of claim 14, wherein a loading/unloading port for loading and unloading the target substrate into and from the processing chamber is provided at a sidewall of the lower space of the processing chamber, and the substrate mounting table is raised and lowered by the mounting table elevation mechanism between the loading/unloading port and a lower end portion of the processing space forming member.

16. The plasma processing apparatus of claim 15, wherein a spot facing hole including a first portion having an inner diameter greater than an outer diameter of the substrate mounting table and a second portion having an inner diameter smaller than the outer diameter of the substrate mounting table is formed at the lower end portion of the processing space forming member, and the substrate mounting table is accommodated in the first portion.

17. The plasma processing apparatus of claim 16, wherein the substrate mounting table is raised by the mounting table elevation mechanism until a clearance having an L-shaped cross section is formed between the substrate mounting table and the first portion, and the substrate mounting table is positioned close to the processing space forming member so as to reduce an exhaust conductance of the clearance having an L-shaped cross section compared to an exhaust conductance of the gas exhaust port.

18. A gas exhaust method of a plasma processing apparatus including a processing chamber forming an inner space; a substrate mounting table provided in the inner space, for mounting thereon a target substrate; a processing space forming member disposed in the inner space, having an inner diameter smaller than an inner diameter of the inner space, for partitioning a processing space for performing plasma processing above the substrate mounting table; and a gas exhaust port provided between an upper end portion of the processing space forming member and an inner wall of the inner space, for exhausting gas from the processing space, the gas exhaust method comprising:
exhausting gas in the processing space from a portion above the substrate mounting table.

19. The gas exhaust method for a plasma processing apparatus of claim 18, wherein a processing gas is introduced into the processing space from a vicinity of the substrate mounting table, and the gas in the processing space is exhausted from a portion above the substrate mounting table.

20. A gas exhaust method for a plasma processing apparatus including a processing chamber forming an inner space; a substrate mounting table provided in the inner space, for mounting thereon a target substrate; a microwave transmitting plate disposed at an upper portion of the processing chamber so as to face a target substrate mounting surface of the substrate mounting table; and a microwave antenna disposed on the microwave transmitting plate, the gas exhaust method comprising:
providing in the inner space a processing space forming member having an inner diameter smaller than an inner diameter of the inner space, for partitioning a processing space for performing plasma processing above the substrate mounting table;
introducing a processing gas from a vicinity of the substrate mounting table into the processing space; and
exhausting the gas in the processing space from a portion above the substrate mounting table.
